(19) United States
(12) Patent Application Publication
(10) Pub. No.: US 2025/0316507 A1
(43) Pub. Date: Oct. 9, 2025

(54) SUBSTRATE PROCESSING SYSTEM AND SUBSTRATE PROCESSING METHOD

(71) Applicant: Tokyo Electron Limited, Tokyo (JP)

(72) Inventors: Hirotoshi MORI, Tokyo (JP); Yohei YAMAWAKI, Kikuchi-gun, Kumamoto (JP); Yohei YAMASHITA, Kikuchi-gun, Kumamoto (JP); Seiji NAKANO, Kikuchi-gun, Kumamoto (JP); Teruhiko MORIYA, Kikuchi-gun, Kumamoto (JP); Takeshi TAMURA, Kikuchi-gun, Kumamoto (JP); Susumu HAYAKAWA, Kikuchi-gun, Kumamoto (JP)

(73) Assignee: Tokyo Electron Limited, Tokyo (JP)

(21) Appl. No.: 18/872,334

(22) PCT Filed: Apr. 25, 2023
(86) PCT No.: PCT/JP2023/016360

§ 371 Date: Dec. 6, 2024

(30) Foreign Application Priority Data
Jun. 7, 2022 (JP) 2022-092479
Dec. 19, 2022 (JP) 2022-202376

(51) Int. Cl. H01L 21/67; G01N 19/00; G01N 21/84; H01L 21/687

(52) U.S. Cl. CPC H01L 21/67092; G01N 19/00; G01N 21/84; H01L 21/67259; H01L 21/68707; H01L 21/68742

(57) ABSTRACT

A substrate processing system of processing a substrate includes a substrate holder having a holding surface on which the substrate is to be held, a driving mechanism for moving the substrate holder in a horizontal direction, a rotating mechanism for rotating the substrate holder, a laser radiator for radiating laser light to the substrate held on the holding surface to form a separation surface serving as a starting point for separation of the substrate, and a detecting mechanism for detecting the separation starting from the separation surface in the substrate held by the substrate holder.

### TECHNICAL FIELD

The various aspects and embodiments described herein pertain generally to a substrate processing system and a substrate processing method.

### BACKGROUND

Patent document 1 discloses a method in which a semiconductor device of a semiconductor substrate, which has a separation oxide film and the semiconductor device formed on a front surface thereof, is transcribed to a destination substrate. The method described in Patent Document 1 includes a process of radiating light from a rear surface of the semiconductor substrate to locally heat the separation oxide film, and a process of causing separation in the separation oxide film and/or at an interface between the separation oxide film and the semiconductor substrate to transcribe the semiconductor device to the destination substrate.

### PRIOR ART DOCUMENT

Patent Document 1: Japanese Patent Laid-open Publication No. 2007-220749

### DISCLOSURE OF THE INVENTION

### Problems to be Solved by the Invention

Exemplary embodiments provide a technique capable of appropriately detecting whether or not a substrate is separated after laser light is radiated and before the substrate is separated starting from a separation surface formed by the radiation of the laser light.

### Means for Solving the Problems

In one exemplary embodiment, a substrate processing system of processing a substrate includes a substrate holder having a holding surface on which the substrate is to be held; a driving mechanism configured to move the substrate holder in a horizontal direction; a rotating mechanism configured to rotate the substrate holder; a laser radiator configured to radiate laser light to the substrate held on the holding surface to form a separation surface serving as a starting point for separation of the substrate; and a detecting mechanism configured to detect the separation starting from the separation surface in the substrate held by the substrate holder.

### Effect of the Invention

According to the exemplary embodiments, it is possible to appropriately detect whether or not the substrate is separated after the laser light is radiated and before the substrate is separated when separating the substrate starting from the separation surface formed by the radiation of the laser light.

### BRIEF DESCRIPTION OF THE DRAWINGS

FIG. 1 is a side view illustrating a schematic structure of a combined wafer as a processing target.

FIG. 2 is a plan view schematically illustrating a configuration of a wafer processing system.

FIG. 3 is a perspective view schematically illustrating a configuration of a wafer transfer device.

FIG. 4 is a side view illustrating a schematic configuration of a laser radiation device.

FIG. 5 is a plan view illustrating a schematic configuration of the laser radiation device.

FIG. 6 is an explanatory diagram illustrating eccentricity between a first wafer and a second wafer.

FIG. 7A and FIG. 7B are side views illustrating an operation of a separating device.

FIG. 8 is an explanatory diagram illustrating a state in which laser light is radiated to a laser absorption layer.

FIG. 9 is a flowchart showing major processes of a wafer processing.

FIG. 10 is an explanatory diagram illustrating an example of radiation of laser light to the laser absorption layer.

FIG. 11 is an explanatory diagram illustrating an unirradiated region in the laser absorption layer.

FIG. 12 is an explanatory diagram illustrating an example of radiation of laser light to the unirradiated region.

FIG. 13 is an explanatory diagram illustrating another example of radiation of laser light to the unirradiated region.

FIG. 14 is an explanatory diagram illustrating still another example of radiation of laser light to the unirradiated region.

FIG. 15 is an explanatory diagram illustrating a flow of a laser light radiating operation on the laser absorption layer.

FIG. 16A to FIG. 16C are explanatory diagrams illustrating a state in which a combined wafer is transferred between a chuck and a transfer arm.

FIG. 17 is an explanatory diagram illustrating a state in which the combined wafer is carried out from the separating device.

FIG. 18 is a side view illustrating another configuration example of the laser radiating device.

FIG. 19 is an explanatory diagram illustrating an example of an unirradiated region, which is not irradiated with laser light, set on the combined wafer.

FIG. 20 is a plan view illustrating a configuration example of a laser radiating device according to another exemplary embodiment.

FIG. 21 is an explanatory diagram simply illustrating an operating principle of a spectral interferometer.

FIG. 22 is an explanatory diagram illustrating a state in which a non-bonding surface is inspected according to another exemplary embodiment.

### DETAILED DESCRIPTION

In a manufacturing process for a semiconductor device, in a combined wafer in which two sheets of semiconductor substrates (hereinafter referred to as “wafers”) are bonded, a device layer formed on a front surface of the second wafer is transcribed to the first wafer. This transcription of the device layer is performed by using, for example, laser lift-off. That is, after reducing bonding strength between the first and second wafers by radiating laser light to an inside of the combined wafer, the second wafer is separated from the first wafer so that the device layer is transcribed to the first wafer.

In a wafer processing system configured to perform this laser lift-off, a laser radiating device that radiates laser light to the combined wafer and a separating apparatus that separates the first wafer and the second wafer may be provided independently. Here, it is assumed that the first wafer and the second wafer may be unintentionally separated after the radiation of the laser light in the laser radiating device. In this case, if such positional misalignment between the first wafer and the second wafer in a horizontal direction is not detected and suppressed, the second wafer may fall off the first wafer due to an inertial force caused by a transfer operation for the combined wafer.

The present disclosure provides a technique capable of appropriately detecting whether or not a substrate is separated after laser light is radiated and before the substrate is separated starting from a separation surface formed by the radiation of the laser light. Further, in the following description, the “separation” of the substrate to be detected refers to a state in which the second wafer is displaced horizontally with respect to the first wafer. More specifically, this state is assumed to include a state in which bonding strength of the second wafer to the first wafer becomes zero so the second wafer can be moved independently with respect to the first wafer, and a state in which although the first wafer and the second wafer are still bonded, the bonding strength is reduced so the second wafer is horizontally displaced from the first wafer.

Hereinafter, a wafer processing system as a substrate processing system and a wafer processing method as a substrate processing method according to an exemplary embodiment will be described with reference to the accompanying drawings. Further, in the present specification and the various drawings, parts having substantially the same functions and configurations will be assigned same reference numerals, and redundant descriptions thereof will be omitted.

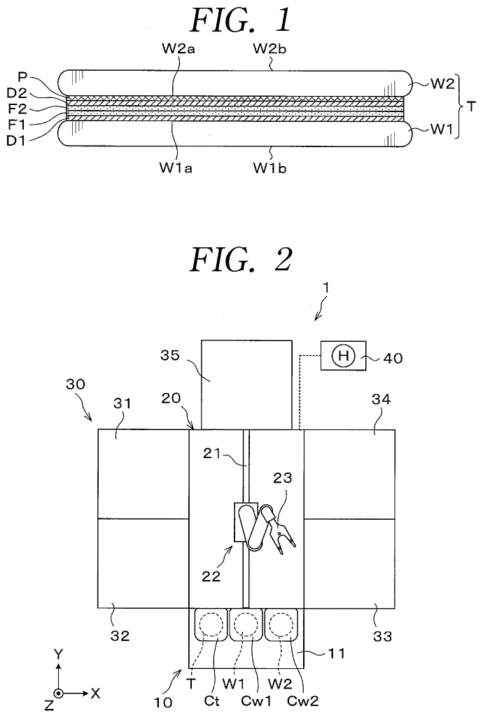

In a wafer processing system 1 according to the present exemplary embodiment, which will be described later, a processing is performed on a combined wafer T as a substrate in which a first wafer W1 and a second wafer W2 are bonded to each other as shown in FIG. 1. Hereinafter, in the first wafer W1, a surface bonded to the second wafer W2 is referred to as a front surface W1a, and a surface opposite to the front surface W1a is referred to as a rear surface W1b. Likewise, in the second wafer W2, a surface bonded to the first wafer W1 is referred to as a front surface W2a, and a surface opposite to the front surface W2a is referred to as a rear surface W2b.

The first wafer W1 as a lower substrate is a semiconductor wafer such as a silicon substrate. In the exemplary embodiment, the first wafer W1 has a substantially circular plate shape. On the front surface W1a of the first wafer W1, a device layer D1 and a surface film F1 are stacked in this order from the front surface W1a side. The device layer D1 includes a plurality of devices. The surface film F1 may be, by way of non-limiting example, an oxide film (a THOX film, a SiO₂ film, a TEOS film), a SiC film, a SiCN film, an adhesive, or the like.

The second wafer W2 as an upper substrate is also a semiconductor wafer such as a silicon substrate. In the present exemplary embodiment, the second wafer W2 has a substantially circular plate shape. On the front surface W2a of the second wafer W2, a laser absorption layer P, a device layer D2, and a surface film F2 are stacked in this order from the front surface W2a side. The laser absorption layer P absorbs laser light radiated from a laser radiator 110, as will be described later. For example, an oxide film (SiO₂ film) is used for the laser absorption layer P. However, the laser absorption layer P is not particularly limited as long as it absorbs the laser light. The device layer D2 and the surface film F2 are the same as the device layer D1 and the surface film F1 of the first wafer W1, respectively. The surface film F1 of the first wafer W1 and the surface film F2 of the second wafer W2 are bonded. Further, the position of the laser absorption layer P is not limited to the above-described exemplary embodiment, and may be formed between the device layer D2 and the surface film F2, for example.

As depicted in FIG. 2, the wafer processing system 1 has a configuration in which a carry-in/out block 10, a transfer block 20, and a processing block 30 are connected as one body. The carry-in/out block 10 and the processing block 30 are provided around the transfer block 20. Specifically, the carry-in/out block 10 is disposed on the negative Y-axis side of the transfer block 20. A laser radiating device 31 (to be described later) and a separating device 32 (to be described later) of the processing block 30 are disposed on the negative X-axis side of the transfer block 20, a first cleaning device 33 to be described later and a second cleaning device 34 to be described later are disposed on the positive X-axis side of the transfer block 20, and an inverting device 35 to be described later is disposed on the positive Y-axis side of the transfer block 20.

In the carry-in/out block 10, cassettes Ct, Cw1, and Cw2 capable of accommodating a plurality of combined wafers T, a plurality of first wafers W1 and a plurality of second wafers W2, respectively, are carried to/from the outside, for example. The carry-in/out block 10 is provided with a cassette placement table 11. In the shown example, a plurality of, for example, the three cassettes Ct, Cw1, and Cw2 can be disposed on the cassette placement table 11 in a row in the X-axis direction. Here, the number of the cassettes Ct, Cw1, and Cw2 placed on the cassette placement table 11 is not limited to the example of the present exemplary embodiment, but can be selected as required.

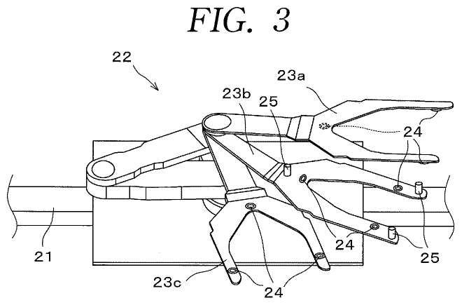

The transfer block 20 is provided with a wafer transfer device 22 as a substrate transfer mechanism configured to be movable on a transfer path 21 extending in the Y-axis direction. The wafer transfer device 22 has a plurality of, for example, three transfer arms 23a to 23c (in the following description, these may be collectively referred to as “transfer arms 23”) each configured to hold and transfer the combined wafer T, the first wafer W1, or the second wafer W2. Each transfer arm 23 has, on a holding surface thereof, attraction members 24 (see FIG. 3) for attracting and holding the combined wafer T, the first wafer W1, or the second wafer W2. Each transfer arm 23 is configured to be movable in a horizontal direction and a vertical direction and pivotable around a horizontal axis and a vertical axis. Further, the wafer transfer device 22 is configured to be able to transfer the combined wafer T, the first wafer W1, and the second wafer W2 to/from the cassettes Ct, Cw1, and Cw2 of the cassette placement table 11, the laser radiating device 31, the separating device 32, the first cleaning device 33, the second cleaning device 34, and the inverting device 35.

As shown in FIG. 3, the three transfer arms 23a to 23c are stacked in this order from the top. The transfer arms 23a to 23c are configured to be pivotable around a vertical axis independently.

At least one of the three transfer arms 23a to 23c (the transfer arm 23b in the middle in the shown example) has a plurality of, for example, three guide pins 25 on a wafer holding surface thereof. The guide pins 25 are arranged to surround the combined wafer T when the combined wafer T is held by the transfer arm 23b. These guide pins 25 suppress the second wafer W2 from falling off the first wafer W1 due to an inertial force or the like caused by the transfer of the combined wafer T by the wafer transfer device 22, as will be described later.

As illustrated in FIG. 3, at least one of the plurality of transfer arms 23a to 23c (the uppermost transfer arm 23a in the shown example) has the attraction members 24 for attracting and holding the combined wafer T, the first wafer W1, or the second wafer W2, that is, the holding surface on a bottom side thereof. The transfer arm 23a having the attraction members 24 on the bottom side thereof attracts and holds the second wafer W2 from above when the second wafer W2 (upper substrate) is carried out from the separating device 32 to be described later.

Here, the configuration of the transfer arm 23 is not limited to the present exemplary embodiment, and the transfer arm 23 may have any of various configurations.

The processing block 30 has the laser radiating device 31, the separating device 32, the first cleaning device 33, the second cleaning device 34, and the inverting device 35. Further, the number and the layout of the laser radiating device 31, the separating device 32, the first cleaning device 33, the second cleaning device 34, and the inverting device 35 are not limited to the shown example.

The laser radiating device 31 radiates laser light to an inside of the combined wafer T, more specifically, to a laser absorption layer P of the second wafer W2 to reduce bonding strength at an interface between the second wafer W2 and the laser absorption layer P. In the present disclosure, the interface with reduced bonding strength within the combined wafer T (the interface between the second wafer W2 and the laser absorption layer P in the present exemplary embodiment) will be referred to as “separation surface.”

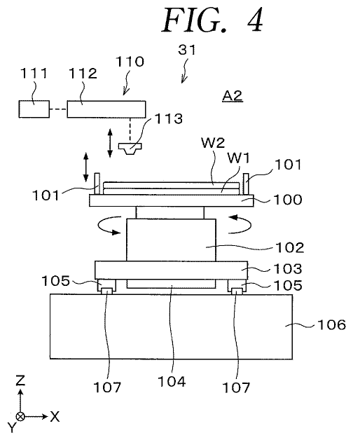

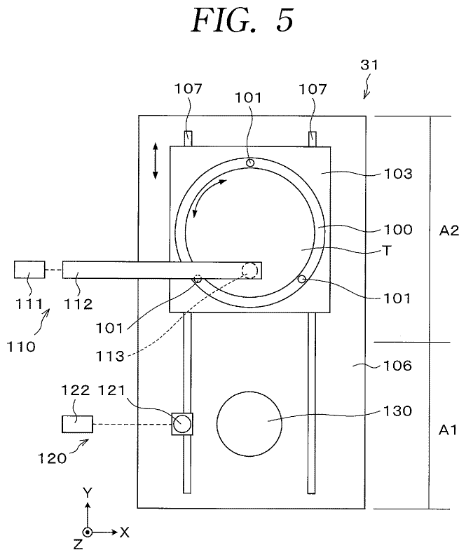

As illustrated in FIG. 4 and FIG. 5, a delivery position A1 and a processing position A2 are set in the laser radiating device 31. The delivery position A1 is a position where the wafer can be handed over between the transfer arm 23 and a chuck 100 to be described later, and where an outer edge of the combined wafer T can be imaged by an imaging mechanism 120 to be described later. The processing position A2 is a position where laser light can be radiated to the combined wafer T (laser absorption layer P) from a laser radiator 110 to be described later.

The laser radiating device 31 has the chuck 100 as a substrate holder configured to hold the combined wafer T on a top surface thereof. The chuck 100 has a wafer holding surface on its top surface, and attracts and holds the entire rear surface W1b of the first wafer W1 or a portion of the radially inner side of the rear surface W1b. The chuck 100 is, for example, an electrostatic chuck (ESC) or a vacuum chuck (Vacuum Chuck).

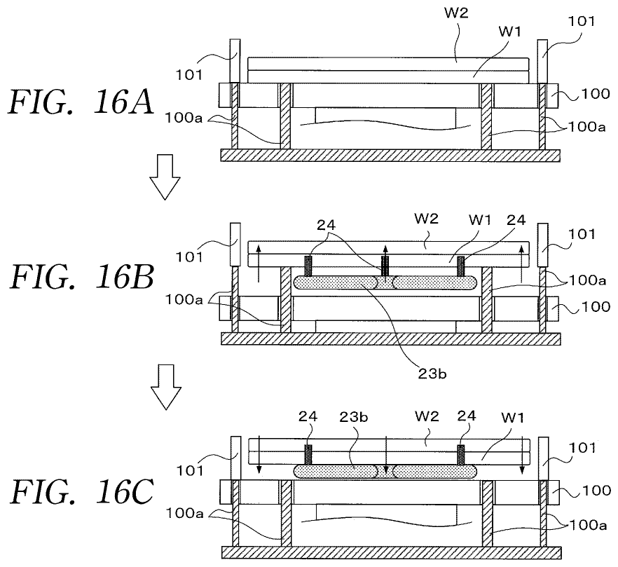

The chuck 100 is also provided with elevating pins 100a (see FIG. 16A to FIG. 16C) configured to support the combined wafer T from below and move it up and down. The elevating pins 100a are configured to be movable up and down through through-holes (see FIG. 16A to FIG. 16C) formed through the chuck 100.

Furthermore, the chuck 100 is provided with multiple, for example, three wafer drop prevention pins 101, as pins for suppressing the substrate from dropping. These wafer drop prevention pins 101 are arranged along a diametrical direction so as to surround the combined wafer T on the holding surface.

The wafer drop prevention pins 101 suppress the second wafer W2 from falling off the first wafer W1 when the second wafer W2 is unintentionally separated from the first wafer W1 during or after the radiation of the laser light due to, for example, a centrifugal force caused by the rotation of the chuck 100 or an inertial force caused by the movement thereof.

The layout of the wafer drop prevention pins 101 is not particularly limited. As an example, in the present exemplary embodiment, the wafer drop prevention pins 101 are configured to be rotatable as one body with the chuck 100 by a rotating mechanism 104 to be described later, also configured to be movable in the Y-axis direction as one body with the chuck 100 by a driving mechanism 105 to be described later, and also configured to be movable up and down in the Z-axis direction as one body with the above-described elevating pins 100a.

The chuck 100 is supported on a slider table 103 with an air bearing 102 therebetween. The rotating mechanism 104 is provided on a bottom side of the slider table 103. The rotating mechanism 104 has, for example, a motor as a driving source embedded therein. The chuck 100 is configured to be rotatable around a θ-axis (vertical axis) by the rotating mechanism 104 via the air bearing 102. The slider table 103 is configured to be movable between the delivery position A1 and the processing position A2 by the driving mechanism 105 provided on the bottom side of the slider table 103, along a rail 107 provided on a base 106 and extending in the Y-axis direction. Although a driving source of the driving mechanism 105 is not particularly limited, a linear motor may be used, for example.

The laser radiator 110 is provided above the chuck 100 at the processing position A2. The laser radiator 110 includes a laser head 111, an optical system 112, and a lens 113.

The laser head 111 has a laser oscillator (not shown) configured to oscillate laser light in a pulse shape. This laser light is so-called pulse-shaped laser. In the present exemplary embodiment, the laser light is CO₂ laser light, and this CO₂ laser light has a wavelength of, e.g., 8.9 μm to 11 μm. The laser head 111 may have other devices of the laser oscillator, such as an amplifier.

The optical system 112 has an optical element (not shown) configured to control the intensity and position of the laser light, and an attenuator (not shown) configured to attenuate the laser light to adjust an output. The optical system 112 may also be configured to be able to control branching of the laser light.

The lens 113 irradiate laser light to the combined wafer T held by the chuck 100. The laser light emitted from the laser radiator 110 passes through the second wafer W2 and is then radiated to the laser absorption layer P. The lens 113 may be configured to be movable up and down by an elevating mechanism (not shown).

In addition, the imaging mechanism 120, as a detecting mechanism, is provided above the chuck 100 at the delivery position A1. The imaging mechanism 120 is equipped with, for example, one or more cameras 121 selected from a macro camera, a micro camera, and so forth, and a calculator 122. The imaging mechanism 120 may be configured to be movable in the Y-axis direction and the Z-axis direction by an elevating mechanism (not shown) or a moving mechanism (not shown).

The camera 121, as an acquirer, images the outer edge of the combined wafer T held by the chuck 100. The camera 121 is equipped with, for example, a coaxial lens, radiates infrared light (IR), and receives reflection light from an object. By imaging the outer edge of the combined wafer T in this way, the camera 121 acquires position information of the combined wafer T (at least the second wafer W2) on the chuck 100.

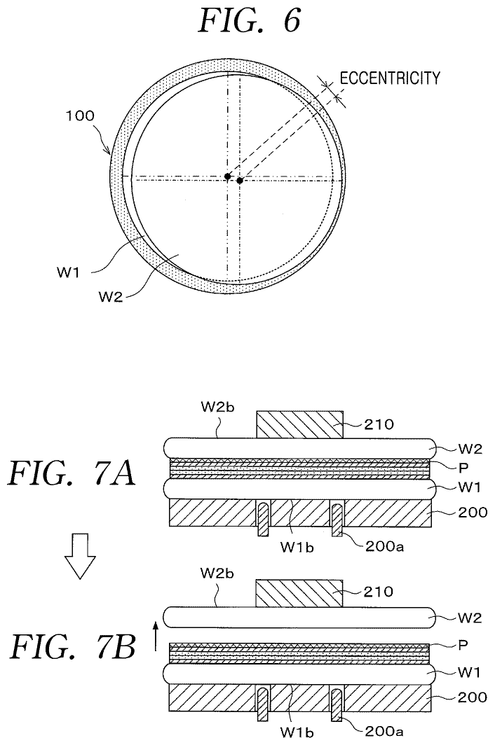

The calculator 122, as a determiner, detects an eccentric amount (a misalignment amount in a horizontal direction (the direction along the separation surface): see FIG. 6) of the second wafer W2 with respect to the first wafer W1 based on the position information of at least the second wafer W2 acquired from the image data acquired by the camera 121. A detailed method of detecting the eccentricity between the first wafer W1 and the second wafer W2 by the imaging mechanism 120 will be discussed later.

In FIG. 6, in order to clearly show the eccentricity between the first wafer W1 and the second wafer W2, the chuck 100 is illustrated not to be equipped with the aforementioned wafer drop prevention pins 101, and the eccentricity between the first wafer W1 and the second wafer W2 is shown to be larger than in an actual case.

Although the calculator 122 may be provided independently as a part of the imaging mechanism 120 as described above, it may be included in a control device 40 to be described later. The imaging result by the camera 121 and the eccentricity calculated by the calculator 122 may be outputted to the control device 40. In other words, the control device 40 may have a function as the acquirer and the determiner according to the technique of the present disclosure.

In the present exemplary embodiment, the “acquirer” of the detecting mechanism according to the technique disclosed herein is explained as “camera 121” configured to image at least the outer edge of the second wafer W2. However, the configuration of the acquirer is not particularly limited thereto as long as it can acquire at least the position of the second wafer W2 on the chuck 100. As a specific example, the “acquirer” of the detecting mechanism according to the technique of the present disclosure may be a length measurement sensor (displacement meter) that acquires position information of the second wafer W2 by measuring at least a distance to the second wafer W2.

In addition, although the present exemplary embodiment has been described for the example where the acquirer (the camera 121 or the length measurement sensor) according to the technique of the present disclosure is disposed above the chuck 100 at the delivery position A1, the acquirer may be disposed next to the chuck 100 as long as it can acquire at least the position of the second wafer W2 on the chuck 100.

A transfer pad 130 is further provided above the chuck 100 at the delivery position A1. The transfer pad 130 is configured to be movable up and down by an elevating mechanism (not shown). The transfer pad 130 has, on a bottom side thereof, an attraction surface for attracting and holding the first wafer W1.

The transfer pad 130 transfers the second wafer W2 between the chuck 100 and the transfer arm 23 when the imaging mechanism 120 has detected the eccentricity between the first wafer W1 and the second wafer W2 in the combined wafer T after the laser light is radiated to the laser absorption layer P. A detailed operation of the transfer pad 130 will be described later.

The separating device 32 separates the second wafer W2 from the first wafer W1 starting from the interface between the second wafer W2 and the laser absorption layer P, which serves as the separation surface with the bonding strength reduced by the laser radiating device 31.

As an example, the separating device 32 has an attraction chuck 200 configured to attract and hold the rear surface W1b of the first wafer W1 from below, and an attraction pad 210 configured to attract and hold the rear surface W2b of the second wafer W2 from above, as shown in FIG. 7A and FIG. 7B. Further, the attraction chuck 200 is provided with elevating pins 200a configured to support the first wafer W1 from below and move it up and down. The elevating pins 200a are configured to be movable through through-holes formed through the attraction chuck 200. In the separating device 32, the attraction pad 210 holding and attracting the second wafer W2 is moved upwards as shown in FIG. 7A and FIG. 7B, so that the second wafer W2 is separated from the laser adsorption layer P.

The configuration of the separating device 32 is not limited to the above-described example, and the separating device 32 may have any of various configurations as long as it is capable of separating the second wafer W2 from the first wafer W1.

The first cleaning device 33 is configured to clean the front surface W1a side of the first wafer W1 separated by the separating device 32. For example, a brush is brought into contact with the laser absorption layer P on the front surface W1a side of the first wafer W1 to clean the laser absorption layer P. Further, the first wafer W1 may be cleaned by using a pressurized cleaning liquid. The first cleaning device 33 may be configured to clean the rear surface W1b of the first wafer W1 along with the front surface W1a side thereof.

The second cleaning device 34 is configured to clean the front surface W2a side of the second wafer W2 separated by the separating device 32. By way of example, a brush is brought into contact with the front surface W2a of the second wafer W2 to clean the front surface W2a. A pressurized cleaning liquid may be used to clean the second wafer W2. The second cleaning device 34 may be configured to clean the rear surface W2b of the second wafer W2 along with the front surface W2a thereof.

In the present exemplary embodiment, although the first cleaning device 33 for cleaning the first wafer W1 and the second cleaning device 34 for cleaning the second wafer W2 are independently provided as described above, the cleaning of the first wafer W1 and the cleaning of the second wafer W2 may be performed by using one and the same cleaning device.

The inverting device 35 is configured to invert top and bottom surfaces of the second wafer W2 after being separated by the separating device 32. That is, the front and rear surfaces of the second wafer W2 are inverted such that the front surface W2a, which is the surface that has been separated from the first wafer W1, faces upwards in the second wafer W2 after being separated. The configuration of the inverting device 35 is not particularly limited.

The above-described wafer processing system 1 is provided with the control device 40 as a control mechanism. The control device 40 is, for example, a computer, and has a program storage (not shown). The program storage stores a program for controlling the processing of the combined wafer T in the wafer processing system 1. The program storage also stores a program for controlling an operation of a driving system such as the various processing apparatuses and the transfer devices described above to implement a wafer processing to be described later in the wafer processing system 1. The programs may be recorded on a computer-readable recording medium H and may be installed from this recording medium H into the control device 40. The recording medium H may be either transitory or non-transitory.

Now, an example of the wafer processing performed by using the wafer processing system 1 configured as described above will be explained. In the present exemplary embodiment, the first wafer W1 and the second wafer W2 are bonded in a bonding apparatus (not shown) outside the wafer processing system 1 to form the combined wafer T in advance.

First, the cassette Ct accommodating the plurality of combined wafers T is placed on the cassette placement table 11 of the carry-in/out block 10.

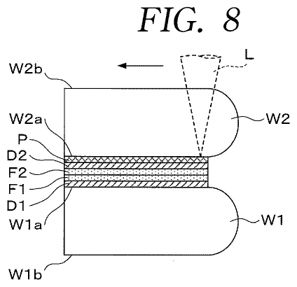

Next, the combined wafer T in the cassette Ct is taken out by the transfer arm 23c of the wafer transfer device 22, and transferred to the laser radiating device 31. In the laser radiator device 31, laser light L (CO₂ laser light) is radiated in a pulse shape from the laser radiator 110 to the laser absorption layer P, more specifically, to the interface between the laser absorption layer P and the second wafer W2, as shown in FIG. 8, to reduce the bonding strength between the laser absorption layer P and the second wafer W2.

A specific wafer processing method in the laser radiating device 31 will be discussed.

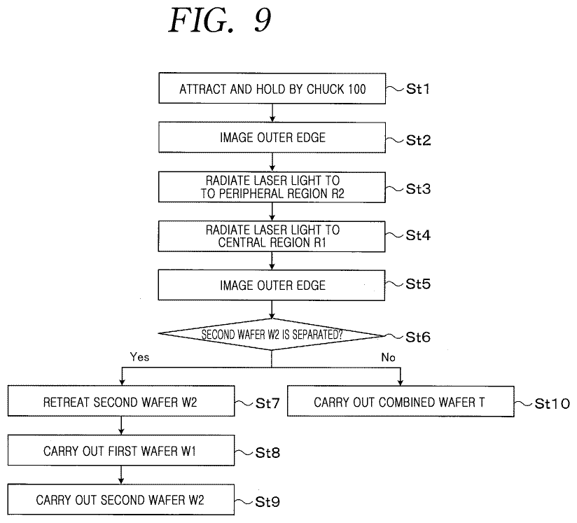

In the laser radiating device 31, the combined wafer T is handed over from the transfer arm 23c onto the chuck 100 placed at the delivery position A1, and is attracted to and held by the chuck 100 (process St1 in FIG. 9).

Subsequently, the outer edge of the combined wafer T (the first wafer W1 and the second wafer W2) attracted to and held on the chuck 100 is imaged by the imaging mechanism 120 (process St2 in FIG. 9). Specifically, while rotating the chuck 100, the outer end of the combined wafer T is imaged in 360 degrees in the circumferential direction by the camera 121 to acquire position information of the combined wafer T (the first wafer W1 and the second wafer W2) on the chuck 100. The imaging result by the camera 121 is outputted to the calculator 122.

Based on the position information of the first wafer W1 and the second wafer W2 on the chuck 100 obtained from the imaging result by the camera 121, the calculator 122 calculates an eccentric amount (see FIG. 6) between the first wafer W1 and the second wafer W2 before being irradiated with the laser light. The calculated eccentric amount between the first wafer W1 and the second wafer W2 before being irradiated with the laser light L is compared with an eccentric amount between the first wafer W1 and the second wafer W2 after being irradiated with the laser light L to be described later to determine whether the first wafer W1 and the second wafer W2 are misaligned, that is, whether the second wafer W2 is separated from the first wafer W1 after they are irradiated with the laser light L.

The calculated eccentric amount between the first wafer W1 and the second wafer W2 before being irradiated with the laser light L may be outputted to the control device 40.

The calculator 122 may also calculate an eccentric amount (a misalignment amount in the horizontal direction) between a rotation center of the chuck 100 and a center of the combined wafer T (first wafer W1 and/or second wafer W2) based on the imaging result by the camera 121. If eccentricity is observed between the rotation center of the chuck 100 and the center of the combined wafer T, it is desirable to perform eccentricity correction control in consideration of the calculated eccentric amount when radiating the laser light L to the laser absorption layer P as will be described later.

The calculated eccentric amount between the rotation center of the chuck 100 and the center of the combined wafer T (second wafer W2) may be outputted to the control device 40.

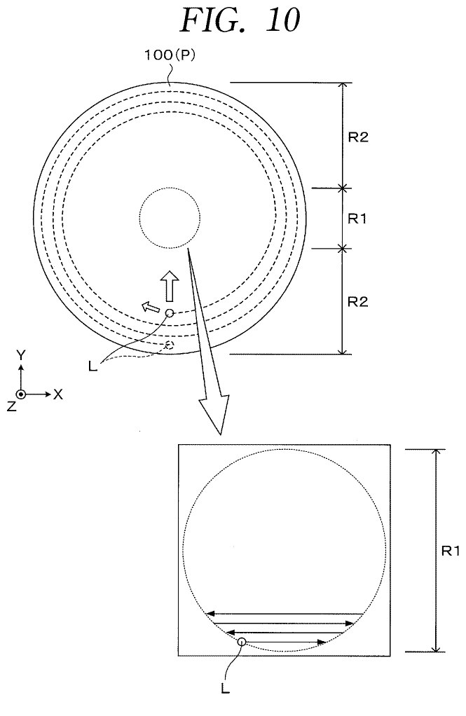

Also, the control device 40 acquires preset positions of a central region R1 and a peripheral region R2 (see FIG. 10) of the chuck 100 to be described later, and sets, based on the imaging result by the camera 121, the central region R1 and the peripheral region R2 on the combined wafer T, which is a target to which the laser light L is to be radiated. More specifically, within the surface of the combined wafer T held by the chuck 100, regions respectively corresponding to the central region R1 and the peripheral region R2 (regions respectively overlapping with the central region R1 and the peripheral region R2 when viewed from the top) are set. The positions of the central region R1 and the peripheral region R2 of the chuck 100 are set based on the rotation center of the chuck 100, and those previously outputted to the control device 40 may be acquired.

Next, the chuck 100 is moved to the processing position A2 by the driving mechanism 105.

Subsequently, the laser radiator 110 starts radiating the laser light L (CO₂ laser light) to the laser absorption layer P, more specifically, to the interface between the laser absorption layer P and the second wafer W2.

Here, in the laser radiating device 31 according to the present exemplary embodiment, the laser light L is radiated in a pulse shape while rotating the combined wafer T held by the chuck 100 by the rotating mechanism 104 and moving the combined wafer T in the Y-axis direction by the moving mechanism 105. Then, the radiation position of the laser light L is moved from a radially outer side toward a radially inner side of the laser absorption layer P, and, as a result, the laser light L is radiated in a spiral shape when viewed from the top, as shown in FIG. 10.

Here, if it is intended to keep the radiation interval of the laser light L constat in order to perform the separation of the second wafer W2 and the laser absorption layer P uniformly within the surface of the wafer, the peripheral speed of the combined wafer T at the radiation position of the laser light L decreases as the radiation position of the laser light L is moved from the radially outer side toward the radially inner side, more specifically, as the radiation position of the laser light L approaches the rotation center of the chuck 100, so it is necessary to increase the rotation speed of the combined wafer T. If, however, the rotation speed of the combined wafer T is increased in this way, there is a risk that the second wafer W2 might be unexpectedly separated from the first wafer W1 due to the centrifugal force caused by the rotation of the combined wafer T, even during the radiation of the laser light L.

In view of this, in the present exemplary embodiment, when radiating the laser light L to the peripheral region R2 (see FIG. 10) of the chuck 100 where the peripheral speed of the combined wafer T is relatively high, the combined wafer T is rotated, whereas when radiating the laser light L to the central region R1 (see FIG. 10) of the chuck 100 where the peripheral speed of the combined wafer T becomes low, the laser light L is scanned in the state that the rotation of the combined wafer T is stopped.

Further, the central region R1 of the chuck 100 where the laser light L is scanned is a circular region having a required length from the rotation center of the chuck 100, and is set in advance prior to the wafer processing in the laser radiating device 31 as stated above. The length of the central region R1 is equivalent to a position in a radial direction at which the relative rotation speed of the chuck 100 with respect to the lens 113 of the laser radiator 110 reaches an upper limit, in other words, a limit position where the laser light L does not overlap. The length of the central region R1 is, for example, about 10 mm.

Further, the peripheral region R2 where the chuck 100 is rotated when the laser light L is radiated is set to be a region outside the central region R1 in the radial direction.

In the radiation of the laser light L to the laser absorption layer P, the laser light L is first radiated to the combined wafer T (laser absorption layer P) in the region corresponding to the peripheral region R2 (process St3 in FIG. 9). At this time, in the laser radiating device 31, by rotating the chuck 100 (combined wafer T) and moving the chuck 100 (combined wafer T) in the Y-axis direction while radiating the laser light L in the pulse shape from the laser radiator 110 as described above, the laser light L is radiated in a spiral shape from the radially outer side toward the radially inner side, as illustrated in FIG. 10. At this time, the laser light L is radiated from the rear surface W2b side (the side opposite to the holding surface) of the second wafer W2 as shown in FIG. 8, penetrates the second wafer W2, and is absorbed into the laser absorption layer P. As a result, the bonding strength at the interface between the laser absorption layer P and the second wafer W2 is reduced.

In the present exemplary embodiment, the term “the bonding strength is reduced” means a state in which the bonding strength is reduced as compared to before the radiation of the laser light L at least. More specifically, this refers to bonding strength not allowing the second wafer W2 to be displaced (separated) in the horizontal direction by the centrifugal force caused by the rotation of the chuck 100 or the inertial force caused by the movement thereof, but allowing the second wafer W2 to be appropriately separated from the first wafer W1 in the separating device 32 to be described later.

Upon the completion of the radiation of the laser light L to the region corresponding to the peripheral region R2 (reduction of the bonding strength between the second wafer W2 and the laser absorption layer P), the laser light L is then radiated to the combined wafer T (laser absorption layer P) in the region corresponding to the central region R1 (process St4 in FIG. 9). In the radiation of the laser light L to the region corresponding to the central region R1, the rotation of the chuck 100 is stopped. Then, while radiating the laser light L from the laser radiator 110 in the pulse shape, scanning of the radiation position of the laser light L in the X-axis direction and moving of the chuck 100 (combined wafer T) in the Y-axis direction by the driving mechanism 105 are alternately repeated (see FIG. 10).

In order to improve the throughput of the wafer processing, the laser light L may be split by the aforementioned optical system 112 to be radiated to multiple points on the laser absorption layer P at the same time.

Further, in the example shown in FIG. 10, when radiating the laser light L to the region corresponding to the central region R1, the scanning of the radiation position in the X-axis direction and the moving of the chuck 100 in the Y-axis direction are alternately repeated. However, the laser light L may be radiated in a spiral shape, the same as in the case of the peripheral region R2. Still alternatively, although not shown, the laser light L may be radiated in a ring shape concentric with the combined wafer T (laser absorption layer P).

Here, when the laser light L is radiated spirally to the laser absorption layer P in the peripheral region R2 as described above, a region not irradiated with the laser light L (unirradiated region) may exist near a boundary between the peripheral region R2 and the central region R1, and this region may correspond to a maximum of about one round along the circumferential direction, as illustrated in FIG. 11. If this region not irradiated with the laser light L exists within the surface of the laser absorption layer P in this way, there is a risk that the laser absorption layer P and the second wafer W2 may not be appropriately separated at a portion corresponding to the unirradiated region in the separating device 32.

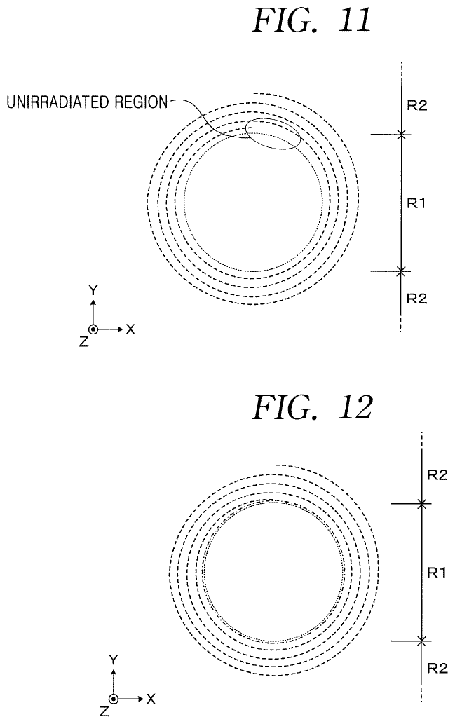

In view of the foregoing, in the laser radiating device 31 according to the present exemplary embodiment, before switching the radiation of the laser light L from the peripheral region R2 to the central region R1, in other words, before stopping the rotation of the chuck 100 in order to radiate the laser light L to the central region R1, the laser light L is radiated to the laser absorption layer P concentrically so as to surround the central region R1, as shown in FIG. 12.

More specifically, when radiating the laser light L to the peripheral region R2, the laser light L is radiated in the spiral shape while rotating the chuck 100 (combined wafer T) and moving it in the Y-axis direction as described above. However, near the boundary between the peripheral region R2 and the central region R1, by stopping moving the chuck 100 (combined wafer T) in the Y-axis direction while carrying on the rotation of the chuck 100 (combined wafer T), the laser light L is radiated to the laser absorption layer P concentrically.

The radiation of the laser light L to the laser absorption layer P in the concentric manner may be performed only one round around the central region R1, as shown in FIG. 12.

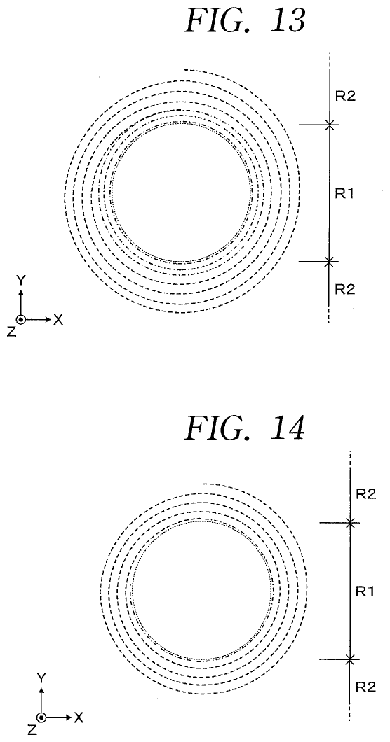

Alternatively, as illustrated in FIG. 13, by alternatively repeating the rotation of the chuck 100 (combined wafer T) by the rotating mechanism 104 and the moving of the chuck 100 (combined wafer T) in the Y-axis direction by the driving mechanism 105 while radiating the laser light L from the laser radiator 110 in the pulse shape, the radiation of the laser light L in the concentric manner may be performed multiple times.

Furthermore, as long as the laser absorption layer P and the second wafer W2 can be appropriately separated, the radiation of the laser light L in the concentric manner may be stopped at one round or less in the circumferential direction (270 degrees in the circumferential direction in the example of FIG. 14), as shown in FIG. 14, to suppress an overlap of the radiation position of the laser light L, which might cause an adverse effect on the device layer.

By radiating the laser light L concentrically in this manner near the boundary between the peripheral region R2 and the central region R1, the size of the unirradiated region that occurs in the laser absorption layer P can be reduced, so that the separation of the laser absorption layer P and the second wafer W2 can be more appropriately performed.

Further, in FIG. 12, FIG. 13, and FIG. 14, the spirally processed portion in the peripheral region R2 is indicated by a dashed line, and the concentrically processed portion is indicated by a dashed dotted line, for the purpose of clear illustration. Actually, however, the radiation interval of the laser light L in both the spirally processed portion and the concentrically processed portion is uniform.

In the example shown in FIG. 10, it is illustrated that the radiation of the laser light L from the radially outer side (near the outer edge of the laser absorption layer P) to the radially inner side (the boundary of the central region R1) in the peripheral region R2 is performed at once. However, in order to control the radiation interval of the laser light L to the peripheral region R2 constant, radiation conditions for the laser light L, such as the frequency of the laser light L, the rotation speed of the chuck 100, the moving speed of the chuck 100 in the horizontal direction, etc., may be changed even in the middle of the radiation of the laser light L to the peripheral region R2.

Alternatively, multiple regions with different conditions regarding the radiation of the laser light L may be formed in the peripheral region R2.

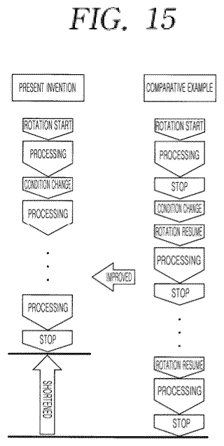

In this case, as shown in a comparative example of FIG. 15, if the rotation of the chuck 100 is stopped/resumed every time the radiation conditions for the laser light L are changed, in other words, if the radiation conditions for the laser light L are changed in the state that the chuck 100 is stopped, it takes time to decelerate and accelerate to stop and resume the rotation, which results in an increase in a processing time.

Therefore, in the laser radiating device 31 according to the present exemplary embodiment, when changing the radiation conditions for the laser light L in the middle of performing the radiation of the laser light L to the peripheral region R2, it is desirable to stop only the radiation of the laser light L to the combined wafer T and the movement of the chuck 100 in the horizontal direction, while carrying on the rotation of the chuck 100.

By keeping on rotating the chuck 100 in this way when changing the radiation conditions for the laser light L, the time required to accelerate and decelerate the rotation speed of the chuck 100 can be reduced, as in an example of the exemplary embodiment shown in FIG. 15, so that the time required for the laser processing can be shortened.

In addition, when changing the radiation conditions for the laser light L while continuing to rotate the chuck 100 in this way, a radiation resume position of the laser light L after the change of the radiation conditions may be the same as a radiation end position of the laser light L before the change of the radiation conditions, or may be a different position therefrom as long as at least the radiation position of the laser light L does not overlap.

When the radiation resume position and the radiation end position of the laser light L are set to be the same, the radiation of the laser light L is not resumed until the radiation end position of the laser light L is located directly under the radiation of the laser light L by the rotation of the chuck 100 after the radiation conditions for the laser light L are changed. In this case, the radiation interval of the laser light L can be controlled to be constant across the entire surface of the laser absorption layer P, so that the separation of the second wafer W2 and the laser absorption layer P can be controlled uniformly in the surface of the wafer.

Meanwhile, when the radiation resume position and the radiation end position of the laser light L are set to be different, the radiation of the laser light L is promptly resumed at a position where at least the radiation position of the laser light L does not overlap after the radiation conditions for the laser light L are changed. In this case, a standby time before the radiation of the laser light L is resumed is reduced, so that the time required for the laser processing can be further shortened.

Once the bonding strength between the second wafer W2 and the laser absorption layer P is reduced in their entire surfaces as the laser light L is radiated to the central region R1 and the peripheral region R2, the chuck 100 (combined wafer T) is then moved to the delivery position A1 by the driving mechanism 105.

Subsequently, at the delivery position A1, the outer edge of the combined wafer T attracted to and held by the chuck 100 is imaged by the imaging mechanism 120 (process St5 in FIG. 9). To elaborate, while rotating the chuck 100, the camera 121 images the outer edge of the combined wafer T in 360 degrees in the circumferential direction, thereby acquiring position information of the combined wafer T (the first wafer W1 and the second wafer W2) on the chuck 100. The imaging result by the camera 121 is outputted to the calculator 122.

In the calculator 122, an eccentric amount (see FIG. 6) between the first wafer W1 and the second wafer W2 after being irradiated with the laser light L is calculated based on the position information obtained from the imaging result by the camera 121. The calculated eccentric amount between the first wafer W1 and the second wafer W2 after being irradiated with the laser light L may be outputted to the control device 40.

The control device 40 calculates a difference value between the eccentric amount between the first wafer W1 and the second wafer W2 before being irradiated with the laser light L and the eccentric amount between the first wafer W1 and the second wafer W2 after being irradiated with the laser light L, and makes a determination upon whether the second wafer W2 has been separated from the first wafer W1 based on the difference value (process St6 in FIG. 9).

In the wafer processing system 1 according to the present exemplary embodiment, the combined wafer T with the reduced bonding strength between the second wafer W2 and the laser absorption layer P is separated into the first wafer W1 and the second wafer W2 in the separating device 32 provided outside the laser radiating device 31.

As stated above, however, if the bonding strength between the second wafer W2 and the laser absorption layer P is reduced by radiating the laser light L, the second wafer W2 may be separated from the laser absorption layer P (first wafer W1) before it is transferred to the separating device 32 due to the inertial force that is generated when the second wafer W2 is moved to the delivery position A1 by the driving mechanism 105 or due to the centrifugal force caused by the rotation of the chuck 100.

If the second wafer W2 is separated before being transferred to the separating device 32, there arises not only a risk that the combined wafer T may not be properly transferred to the separating device 32, but also a risk that the second wafer W2 may fall down in the system, causing a problem.

In the laser radiating device 31 according to the present exemplary embodiment, however, it is possible to determine in the process St6 whether or not the second wafer W2 has been separated from the first wafer W1 before the combined wafer T is transferred to the separating device 32. Accordingly, it is possible to suppress the combined wafer T in which the second wafer W2 has been separated from the first wafer W1 from being transferred to the separating device 32 by the wafer transfer device 22, so that the risk of the second wafer W2 falling down in the system can be reduced.

Further, in the present exemplary embodiment, at least three wafer drop prevention pins 101 are provided so as to surround the combined wafer T held by the chuck 100, as illustrated in FIG. 4 and FIG. 5. This suppresses the second wafer W2 from falling down in the laser radiating device 31 after the laser light L is radiated to the laser absorption layer P, even when the second wafer W2 has been separated from the first wafer W1.

In a case where the combined wafer T is determined in the process St6 to be in the state that the second wafer W2 has been separated from the first wafer W1, the transfer pad 130 is first raised in the state that the rear surface W2b of the second wafer W2 is attracted to and held by the transfer pad 130, thus allowing the second wafer W2 to be separated from the first wafer W1 (process St7 in FIG. 9).

Next, the first wafer W1 on the chuck 100 is handed over to the transfer arm 23c of the wafer transfer device 22, and the first wafer W1 is carried out from the laser radiating device 31 (process St8 in FIG. 9). At this time, if the eccentric amount (positional misalignment) of the first wafer W1 with respect to the chuck 100 is known in the process St2, the insertion position of the transfer arm 23c may be adjusted according to this eccentric amount.

Subsequently, the second wafer W2 attracted to and held by the transfer pad 130 is delivered to the transfer arm 23a of the wafer transfer device 22, and the second wafer W2 is carried out from the laser radiating device 31 (process St9 in FIG. 9). At this time, in order to attract and hold the rear surface W2b (the surface opposite to the one separated from the first wafer W1) of the second wafer W2, it is desirable to use the transfer arm 23a that is configured to attract and hold the second wafer W2 from above. Further, the second wafer W2 may be transferred to the transfer arm 23a via the chuck 100.

The first wafer W1 taken out from the laser radiating device 31 is then transferred by the wafer transfer device 22 to the cassette Cw1 of the cassette placement table 11. Further, the second wafer W2 carried out from the laser radiating device 31 is transferred by the wafer transfer device 22 to the cassette Cw2 of the cassette placement table 11 after top and bottom surfaces thereof are inverted in the inverting device 35, that is, after its surface separated from the first wafer W1 is turned to face up. At this time, the first wafer W1 and the second wafer W2 may be transferred to the cassettes Cw1 and Cw2 of the cassette placement table 11, respectively, after their surfaces W1a and W2a, which are the surfaces separated from each other, are cleaned in the first cleaning device 33 and the second cleaning device 34, respectively.

Meanwhile, the combined wafer T, for which it has been determined in the process St6 that the second wafer W2 has not been separated from the first wafer W1, is transferred from the chuck 100 to the transfer arm 23b of the wafer transfer device 22, and is carried out from the laser radiating device 31 (process St10 in FIG. 9).

Here, if the separation of the second wafer W2 is not appropriately detected in the above-described process St6 even though the second wafer W2 is actually separated from the first wafer W1, there is a risk that the second wafer W2 may fall down in the system due to, for example, an impact applied to the combined wafer T when it is transferred from the chuck 100 to the transfer arm 23, or due to an inertial force that is generated when the combined wafer T is transferred by the transfer arm 23.

To resolve this risk, in the laser radiating device 31 according to the present exemplary embodiment, the wafer drop prevention pins 101 arranged to surround the combined wafer T held by the chuck 100 are configured to be movable up and down in the Z-axis direction as one body with the elevating pins 100a.

The transfer of the combined wafer T from the chuck 100 to the transfer arm 23b is carried out through a series of operations of supporting and raising the combined wafer T from below with the elevating pins 100a, inserting the transfer arm 23b between the holding surface of the chuck 100 and the bottom surface of the combined wafer T (the rear surface W1b of the first wafer W1), and then lowering the combined wafer T with the elevating pins 100a.

At this time, as shown in FIG. 16A to FIG. 16C, by raising and lowering the wafer drop prevention pins 101 as one body with the elevating pins 100a, the combined wafer T can still be surrounded by the wafer drop prevention pins 101 even at the time when the wafer is raised by the elevating pins 100a, so that the second wafer W2 can be suppressed from falling down when the combined wafer T is transferred from the chuck 100 to the transfer arm 23b.

In addition, in the wafer processing system 1 according to the present exemplary embodiment, when transferring the combined wafer T after being irradiated with the laser light L from the laser radiating device 31 to the separating device 32, the transfer arm 23b having the guide pins 25 arranged to surround the combined wafer T on the holding surface is used.

Therefore, even if the second wafer W2 has been separated from the first wafer W1, the second wafer W2 can be suppressed from falling down due to the inertial force when the combined wafer T is transferred from the laser radiating device 31 to the separating device 32.

The combined wafer T taken out from the laser radiating device 31 is then transferred to the separating device 32 by the wafer transfer device 22. In the separating device 32, the rear surface W1b of the first wafer W1 is attracted to and held by the attraction chuck 200, and the rear surface W2b of the second wafer W2 is attracted to and held by the attraction pad 210, as depicted in FIG. 7A and FIG. 7B. Thereafter, with the second wafer W2 attracted to and held by the attraction pad 210, the attraction pad 210 is raised to separate the second wafer W2 from the first wafer W1. At this time, since the bonding strength at the interface between the laser absorption layer P and the second wafer W2 is reduced as a result of the radiation of the laser light L as described above, the second wafer W2 can be separated without having to apply a big load.

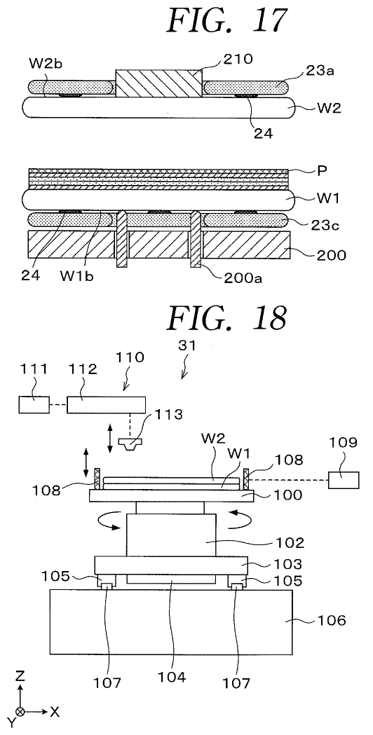

The separated second wafer W2 is delivered from the attraction pad 210 onto the transfer arm 23a of the wafer transfer device 22, as shown in FIG. 17, and is then transferred to the inverting device 35. Then, after the second wafer W2 is turned upside down in the inverting device 35 so that the front surface W2a thereof faces upwards, the second wafer W2 is transferred to the second cleaning device 34.

In the second cleaning device 34, the front surface W2a, which is the surface separated from the first wafer W1, is cleaned. Also, in the second cleaning device 34, the rear surface W2b as well as the front surface W2a may be cleaned. Furthermore, separate cleaning devices may be provided to clean the front surface W2a and the rear surface W2b separately.

Thereafter, the second wafer W2 cleaned by the second cleaning device 34 is transferred to the cassette Cw2 of the cassette placement table 11 by the wafer transfer device 22.

Meanwhile, the first wafer W1 held by the attraction chuck 200 is delivered onto the transfer arm 23c as shown in FIG. 17, and is transferred to the first cleaning device 33. This transfer by the transfer arm 23c may be performed simultaneously with the transfer of the second wafer W2 by the transfer arm 23a, or may be performed independently. In the first cleaning device 33, the front surface W1a side, which is the one separated from the second wafer W2, specifically, the front surface of the laser absorption layer P is cleaned. Further, in the first cleaning device 33, the rear surface W1b of the first wafer W1 may be cleaned along with the front surface of the laser absorption layer P. Also, separate cleaning devices may be provided to clean the front surface of the laser absorption layer P and the rear surface W1b of the first wafer W1 separately.

Thereafter, the first wafer W1 cleaned by the first cleaning device 33 is transferred by the wafer transfer device 22 to the cassette Cw1 on the cassette placement table 11.

In this way, the series of processes of the wafer processing in the wafer processing system 1 are completed.

In the laser radiating device 31 according to the above-described exemplary embodiment, the separation of the second wafer W2 is detected based on the difference in the eccentric amount of the second wafer W2 with respect to the first wafer W1 before and after the radiation of the laser light L to the combined wafer T (laser absorption layer P) as described above. However, the configuration of the detecting mechanism for the second wafer W2 and the detection method using the same are not particularly limited, and at least one of the following configurations and methods may be adopted instead of or in addition to the above-described configuration and method.

(1) As stated above, in case that no eccentricity (misalignment in the horizontal direction) occurs even though the second wafer W2 is actually separated from the first wafer W1 after the laser light L is radiated to the combined wafer T (laser absorption layer P), the separation of the second wafer W2 cannot be properly detected.

As a resolution, after the laser light L is radiated to the combined wafer T in the laser radiating device 31, a load may be applied to the combined wafer T when the chuck 100 is moved from the processing position A2 to the delivery position A1, thereby making the second wafer W2 shifted from the first wafer W1 (moving the second wafer W2 in the horizontal direction). More specifically, by setting an acceleration for moving the chuck 100 from the processing position A2 to the delivery position A1 after the radiation of the laser light L to be larger than an acceleration for moving the chuck 100 from the delivery position A1 to the processing position A2 before the radiation of the laser light L, an inertial force as the load may be applied to the combined wafer T.

At this time, the load applied to the combined wafer T after the radiation of the laser light L is controlled to be of a magnitude that causes the separated second wafer W2 to be shifted on the first wafer W1 but does not cause the second wafer W2 to be shifted on the first wafer W1 (to be separated) when the second wafer W2 is not separated.

According to the above-described method (1), the load is intentionally applied to the combined wafer T after being irradiated with the laser light L, thereby intentionally causing the eccentricity (misalignment in the horizontal direction) between the first wafer W1 and the second wafer W2. This makes it possible to avoid the aforementioned state in which no eccentricity occurs even though the second wafer W2 is actually separated from the first wafer W1. As a result, the risk that the second wafer W2 might fall off the first wafer W1 in the system can be further appropriately suppressed.

In addition, according to the above-described method (1), the tact time required for the processing in the laser radiating device 31 can be reduced by intentionally causing the eccentricity between the first wafer W1 and the second wafer W2.

To elaborate, according to the above-described method (1), by intentionally creating the eccentricity between the first wafer W1 and the second wafer W2, the eccentricity can be detected by imaging at least a part of the outer edge of the combined wafer T, for example, only one point in the circumferential direction, instead of imaging the outer edge of the combined wafer T in 360 degrees in the circumferential direction. Therefore, at least the time required to image the outer edge after the radiation of the laser light L to the combined wafer T (laser absorption layer P) can be reduced, so that the tact time can be reduced.

(2) In the laser radiating device 31, instead of or in addition to the wafer drop prevention pins 101 shown in FIG. 4 and FIG. 5, a plurality of, for example, three contact sensors 108, as detectors, and a calculator 109, as a determiner configured to make a determination upon the separation of the second wafer W2 with the contact sensors 108, may be arranged so as to surround the combined wafer T on the holding surface of the chuck 100 as illustrated in FIG. 18. In this case, instead of or in addition to the imaging mechanism 120 according to the above-described exemplary embodiment, the contact sensors 108 and the calculator 109 constitute the detecting mechanism according to the technique of the present disclosure.

Further, the calculator 109 may be independently disposed in the laser radiating device 31 or may be included in the control device 40.

According to the above-described configuration (2), instead of imaging the outer edge of the combined wafer T after the radiation of the laser light L to the combined wafer T (laser absorption layer P), the separation of the second wafer W2 can be detected only by determining whether or not the contact sensors 108 are in contact with the second wafer W2. Therefore, the imaging of the outer edge by the imaging mechanism 120 after the radiation of the laser light L to the combined wafer T (laser absorption layer P) can be omitted, so that the tact time for the processing in the laser radiating device 31 can be reduced.

Furthermore, in the wafer processing system 1 according to the technique of the present disclosure, both the contact sensors 108 and the imaging mechanism 120 as the detecting mechanism may be disposed in the laser radiating device 31. In this case, the detection of the separation of the first wafer W1 and the second wafer W2 by the imaging mechanism 120 and by the contact sensors 108 may be both carried out.

In this case, when the contact between the contact sensors 108 and the second wafer W2 is detected, the detection of the separation of the first wafer W1 and the second wafer W2 by the imaging mechanism 120 (imaging of the outer edge of the combined wafer T) may be omitted.

(3) In the above-described exemplary embodiment, the separation of the second wafer W2 is detected based on the difference in the eccentric amount between the first wafer W1 and the second wafer W2 before and after the radiation of the laser light L, which is obtained by imaging the outer edge of the combined wafer T (the first wafer W1 and the second wafer W2) with the imaging mechanism 120.

However, the imaging of the outer edge of the combined wafer T (the first wafer W1 and the second wafer W2) by the imaging mechanism 120 does not necessarily have to be performed before and after the radiation of the laser light L, but may be performed only after the radiation of the laser light L.

In the above-described method (3) as well, if it is possible to image the outer edge of the combined wafer T (first wafer W1 and second wafer W2), at least after the radiation of the laser light L, and obtain the eccentric amount (misalignment amount in the horizontal direction) between the first wafer W1 and the second wafer W2, the determination on whether or not the second wafer W2 has been separated can be made based on the eccentric amount.

(4) In the above-described exemplary embodiment, the separation of the second wafer W2 is detected based on the difference in the eccentric amount between the first wafer W1 and the second wafer W2 before and after radiation of the laser light L, which is obtained by imaging the outer edge of the combined wafer T (the first wafer W1 and the second wafer W2) with the imaging mechanism 120.

However, depending on a factor such as an angle of view or an imaging magnification of the imaging mechanism 120, the imaging mechanism 120 may not be able to image the outer edge of the first wafer W1 as the lower substrate on the chuck 100.

Thus, in the wafer processing system 1 according to the technique of the present disclosure, the imaging mechanism 120 may image only the outer edge of the second wafer W2 as the upper substrate.

In this case, the position information of the second wafer W2 on the chuck 100 before and after the radiation of the laser light L is obtained from the imaging result by the imaging mechanism 120, and the eccentric amounts (misalignment amounts) of the center (more specifically, the rotation center) of the second wafer W2 in the horizontal direction with respect to the center of the chuck 100 before and after the radiation of the laser light L are detected. Then, by calculating a difference between the eccentric amount of the center of the second wafer W2 with respect to the center of the chuck 100 before the radiation of the laser light and the eccentric amount of the center of the second wafer W2 with respect to the center of the chuck 100 after the radiation of the laser light, it is possible to make a determination on the separation of the second wafer W2 based on this difference.

According to the above-described method (4), even when the imaging mechanism 120 cannot properly image the outer edge of the combined wafer T (the first wafer W1 and the second wafer W2), the separation of the second wafer W2 can still be detected by acquiring at least the position information of the second wafer W2.

(5) In the above-described exemplary embodiment, by imaging the outer edge of the combined wafer T (the first wafer W1 and the second wafer W2) in 360 degrees in the circumferential direction with the imaging mechanism 120, the eccentric amount between the first wafer W1 and the second wafer W2 is calculated, and the separation of the second wafer W2 is detected.

However, the imaging mechanism 120 does not necessarily need to image the outer edge of the combined wafer T (the first wafer W1 and the second wafer W2) in 360 degrees in the circumferential direction. The separation of the second wafer W2 can be detected by imaging at least two points of the combined wafer T in the circumferential direction (for example, a point of 0 degree in the circumferential direction as a reference position and a point of 90 degrees from the reference position in the circumferential direction).

According to the above-described method (5), the separation of the second wafer W2 can be detected by imaging the outer edge of the combined wafer T at two points in the circumferential direction, instead of imaging the outer edge of the combined wafer T in 360 degrees in the circumferential direction. Therefore, the time required to image the outer edge by the imaging mechanism 120 after the radiation of the laser light L can be shortened, so that the tact time for the processing in the laser radiating device 31 can be reduced.

(6) In the above-described exemplary embodiment, the bonding strength between the second wafer W2 and the laser absorption layer P is reduced by radiating the laser light L to the central region R1 and the peripheral region R2 from the laser radiator 110.

If, however, the bonding strength is reduced in the entire surfaces of the second wafer W2 and the laser absorption layer P in this manner, there is a risk that the second wafer W2 might fall down due to the inertial force in the transfer of the combined wafer T as mentioned above.

Therefore, in the wafer processing system 1 according to the technique of the present disclosure, the radiation of the laser light L may be stopped in at least a partial region of the interface between the second wafer W2 and the laser absorption layer P, and the bonding strength between the second wafer W2 and the laser absorption layer P may be maintained in the at least partial region that is not irradiated with the laser light L.

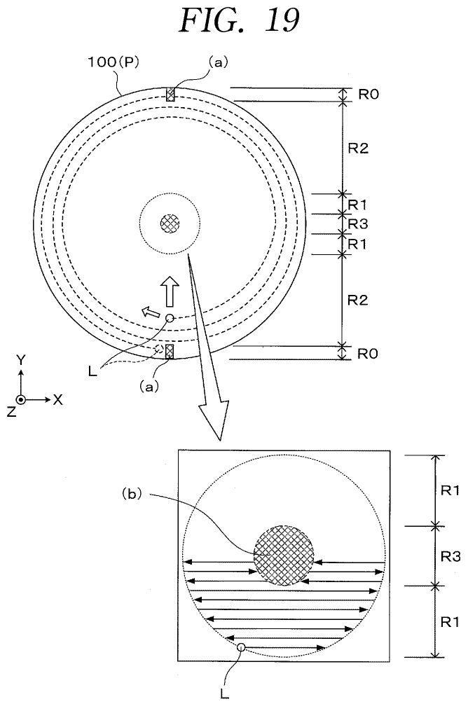

More specifically, in the wafer processing system 1, as shown in FIG. 19, a region in which the bonding strength between the second wafer W2 and the laser absorption layer P is not reduced may be formed in a part of an outermost peripheral region RO (see, portion (a) in FIG. 19) set to be an outermost position of the peripheral region R2, or in a central region R3 (see, portion (b) in FIG. 19) set near the center position of the central region R1 at the interface between the second wafer W2 and the laser absorption layer P.

According to the above-described method (6), by forming, at least in a part of the interface between the second wafer W2 and the laser absorption layer P, the region in which the bonding strength is not reduced (to which the laser light L is not radiated), the second wafer W2 is not separated from the first wafer W1 in that region, so that it is possible to suppress the second wafer W2 from falling down due to the inertial force acting on the combined wafer T.

In the wafer processing system 1 according to the technique of the present disclosure, by detecting the separation of the second wafer W2 before carrying out the combined wafer T from the laser radiating device 31 by adopting at least one of the above-described exemplary embodiment and methods (1) to (6), it is possible to suppress a risk that the second wafer W2 might fall off the first wafer W1 in the system.

Furthermore, when performing at least one of the above-described methods (1) to (6) in this manner as well, the “acquirer” of the detecting mechanism can use a length measurement sensor (displacement meter) instead of the camera 121, as stated above.

Additionally, in the above-described exemplary embodiment, when the separation of the second wafer W2 is detected in the process St6 as shown in FIG. 9, the first wafer W1 and the second wafer W2 are carried out from the laser radiating device 31 in sequence (in the processes St8 and St9). However, the operation performed when the separation is detected is not limited thereto.

By way of example, instead of independently carrying out the first wafer W1 and the second wafer W2 from the laser radiating device 31 as described above, the first wafer W1 and the second wafer W2 may be simultaneously taken out from the laser radiating device 31 by using the transfer arm 23b equipped with the guide pins 25, as in the process St10. In this case, in order to suppress the second wafer W2 from falling from the first wafer W1, it is desirable to control the elevating speed of the combined wafer T by the elevating pins 100a or the transfer speed of the combined wafer T by the wafer transfer device 22 to a speed lower than a specified speed, which is a moving speed under normal circumstances (when the separation of the second wafer W2 is not detected in the process St6).

Also, for example, if the separation of the first wafer W1 and the second wafer W2 is detected in the process St6 and it is determined that it is difficult to transfer the combined wafer T by the wafer transfer device 22, an alarm may be set off by the control device 40, and the subsequent processing may be stopped. In this case, the combined wafer T may be removed from the laser radiating device 31 manually by an operator.

In the above-described exemplary embodiment, the wafer processing method of the present disclosure is applied when performing the laser lift-off to separate the second wafer W2 from the laser absorption layer P. However, the technique of the present disclosure can be applied to any of various cases where at least a part of the first wafer W1 and/or the second wafer W2 is separated from the combined wafer T in which the first wafer W1 and the second wafer W2 are bonded to each other.

For example, in a manufacturing process for a semiconductor device, laser light is radiated to an inside of a silicon substrate of a wafer, which has a plurality of devices such as electronic circuits formed on a front surface thereof, along a plane direction to form a modification layer, and the wafer is thinned by being separated starting from the modification layer as a separation surface. YAG laser light is used as this laser light. The technique of the present disclosure can also be applied to form this modification layer serving as a separation surface which is a starting point for thinning the wafer in this way.

Furthermore, the technique of the present disclosure is also applicable to a debonder technique of separating the first wafer W1 and the second wafer W2 in the combined wafer T in which the first wafer W1 and the second wafer W2 are bonded together.

In addition, when forming the modification layer by radiating the laser light to the inside of the silicon substrate and separating the wafer starting from the modification layer as described above, it is only needed to detect positional misalignment between a lower wafer held by the chuck 100 and an upper wafer to be removed by the separation, instead of detecting a positional misalignment amount in the horizontal direction between the first wafer W1 and the second wafer W2 described in the above exemplary embodiment.

As a specific example, a spectral interferometer may be disposed in the laser radiating device 31 instead of the imaging mechanism 120 or the length measurement sensor, and a space formed at the interface between the first wafer W1 and the second wafer W2 (more specifically, the interface between the second wafer W2 and the laser absorption layer P) may be detected in the thickness direction of the combined wafer T (position information of the combined wafer T in the height direction) to determine whether the second wafer W2 has been separated from the first wafer W1.

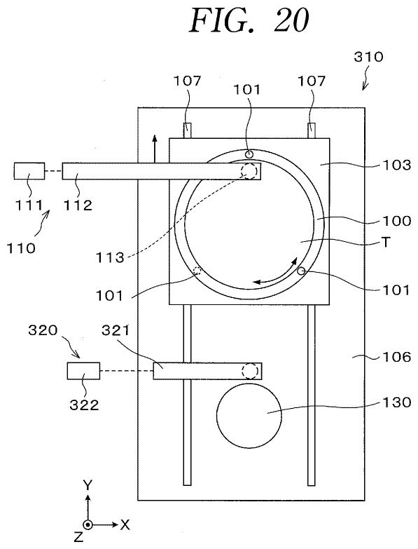

As depicted in FIG. 20, a spectral interferometer 320 is disposed in a laser radiating device 310 according to another exemplary embodiment. The spectral interferometer 320 has a head 321 and an analyzer 322.

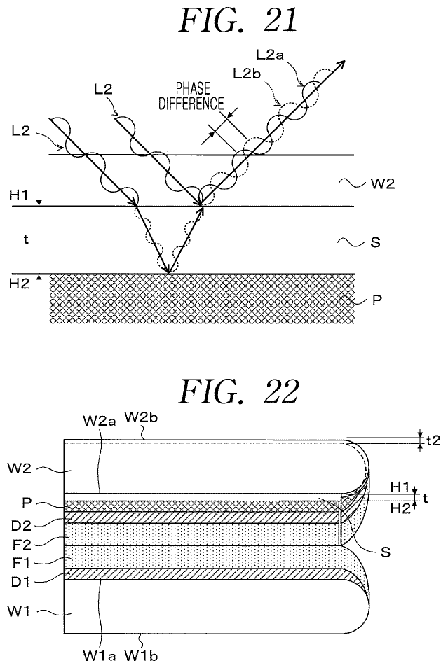

The head 321 has a non-illustrated radiator configured to radiate measurement light to the combined wafer T on the chuck 100, and a non-illustrated spectroscopic device that is configured to receive the measurement lights (reflection lights) reflected at different height positions (a first height position H1 and a second height position H2: see FIG. 21 and FIG. 22) of the combined wafer T and detect interference between the reflection lights. As the measurement light radiated from the radiator, light having penetrability for the second wafer W (silicon) is selected as required.

The analyzer 322 calculates a distance between the first height position H1 and the second height position H2 by detecting the interference between the reflection lights from the first height position H1 and the second height position H2 detected by the head 321. The analyzer 322 may be embedded in the control device 40.

Now, a method of determining whether the second wafer W2 is separated from the first wafer W1 by using the spectral interferometer 320 will be explained.

The combined wafer T in which the bonding strength between the second wafer W2 and the laser absorption layer P are reduced in their entire surfaces as a result of radiating the laser light L to the central region R1 and the peripheral region R2 by the same method as in the above-described exemplary embodiment is moved to below the spectral interferometer 320 by the driving mechanism 105. Then, while rotating the chuck 100, measurement light L2 is radiated toward the combined wafer T from the radiator of the head 321, and the reflection light from the combined wafer T is directed into the spectroscopic device, as illustrated in FIG. 21. In the spectroscopic device, when interference (reflection spectrum) of the reflection light is detected in the entire surface of the combined wafer T, it is determined that the second wafer W2 is separated from the first wafer W1.

At this time, however, when the chuck 100 holding the combined wafer T with the reduced bonding strength in the entire surfaces of the second wafer W2 and the laser absorption layer P is moved and rotated, there is a risk that the second wafer W2 may fall off the first wafer W1.

In view of this, when moving and rotating the chuck 100 holding the combined wafer T with the reduced bonding strength in the entire surfaces of the second wafer W2 and the laser absorption layer P, it is desirable to reduce the moving speed and the rotation speed. Alternatively, instead of moving and rotating the chuck 100, the spectral interferometer 320 may be moved and rotated relative to the chuck 100 (combined wafer T) from above the chuck 100. As another example, the spectral interferometer 320 and the laser radiator device 310 may be configured side by side or as one body, and reducing the bonding strength by the laser radiating device 310 and making the determination upon the separation by the spectral interferometer 320 may be performed simultaneously or consecutively.

A more specific method of determining upon the separation between the second wafer W2 and the first wafer W1 by using the spectral interferometer 320 will be discussed.

When the second wafer W2 has been separated from the first wafer W1 due to the reduced bonding strength at the interface between the second wafer W2 and the laser absorption layer P as a result of radiating the laser light L, it is assumed that a space S, which is a gap between the second wafer W2 and the first wafer W1, is formed at the separation surface between the second wafer W2 and the first wafer W1 (at the interface between the second wafer W2 and the laser absorption layer P in the shown example), as illustrated in FIG. 21 and FIG. 22.

When the space S exists at the interface between the second wafer W2 and the laser absorption layer P, the measurement light L2 is reflected at each of the first height position H1 and the second height position H2, which is respectively located at the top and the bottom of this space, and reflection lights L2a and L2b from the respective height positions reach the spectroscopic device, as shown in FIG. 21.

Once the spectroscopic device detects interference (reflection spectrum) of these reflection lights L2a and L2b, the analyzer 322 calculates a thickness t of the space S (a distance between the first height position H1 and the second height position H2) based on this reflection spectrum. The calculated thickness t of the space S is outputted to the control device 40.

Based on the received thickness t, the control device 40 can make a determination upon whether or not the space S is formed at the interface between the second wafer W2 and the laser absorption layer P. If it is determined that the space S is formed in the entire surface of the combined wafer T (laser absorption layer P), there may be made a determination that the second wafer W2 and the laser absorption layer P are completely separated, and the second wafer W2 is thus separated from the first wafer W1.

In one example, whether or not the space S is formed at the interface (separation surface) between the second wafer W2 and the laser absorption layer P can be determined by comparing the measurement result (thickness t) obtained by the spectral interferometer 320 after the radiation of the laser light L to the combined wafer T with a preset first threshold value. When the measurement result exceeds the preset first threshold value, it is determined that the space S is formed. The first threshold value used for the comparison may be, by way of example, a value obtained by performing the measurement on the same combined wafer T before the radiation of the laser light L in the laser radiating device 31. That is, the first threshold value may be used to compare a measurement result obtained in the state where the laser light L is not radiated (no space S is formed) with a measurement result obtained in the state where the laser light L is radiated (the space S is formed). Alternatively, the first threshold value may be one obtained in advance from a different wafer (for example, a dummy wafer, etc.). That is, the first threshold value may be used to compare a measurement result in the different wafer in which bonding strength has been reduced by radiation of the laser light L with a measurement result in an actual wafer in which bonding strength has been reduced by radiation of the laser light L.

The calculated thickness t of the space S may be used as the first threshold value. In this case, the first threshold value is a value at which it is determined that the space S is formed, and the thickness t at which it is determined that the space S is formed is a value greater than 0 (t>0). The first threshold value used for the comparison may be set to be a value greater than 0.

Then, in the control device 40, when the region of the interface exceeding the first threshold value satisfies a predetermined second threshold value, it is determined that the second wafer W2 is not separated from the first wafer W1 and the second wafer W2 will not fall down. The second threshold value is set within a range in which the second wafer W2 is unlikely to fall from the first wafer W1 during the subsequent transfer of the combined wafer T or the like. The second threshold value is set through previous experiment or simulation, for example. A ratio of the area of the region in which the space S is formed to the total area of the combined wafer T (laser absorption layer P), when viewed from the top, may be used as the second threshold value.

In addition, it is desirable that the detection of the reflection light from the combined wafer T using the spectral interferometer 320 is performed on the entire surface of the combined wafer T (laser absorption layer P) in order to properly detect the separation of the second wafer W2 from the first wafer W1. However, for the purpose of shortening the time required for the inspection to improve throughput, the detection of the reflection light may be performed only on a part of the combined wafer T with respect to a radiation pitch of the laser light L radiated to the laser absorption layer P (for example, only on a part of the combined wafer T in the radial direction or circumferential direction). Alternatively, as shown in FIG. 19, for example, when a region in which bonding strength is not supposed to be reduced is formed in a part of the interface between the second wafer W2 and the laser absorption layer P, only this region where the bonding strength is not supposed to be reduced may be inspected, and if no separation is detected (if the thickness t is zero (t=0)), there may be made a determination that the first wafer W1 and the second wafer W2 are not separated.

Further, in the above-described another exemplary embodiment, although the spectral interferometer 320 configured to detect the separation of the first wafer W1 and the second wafer W2 is disposed inside the laser radiating device 310, the spectral interferometer 320 may be provided outside the laser radiating device 310. That is, in the technique according to the present disclosure, the laser radiating device 31 and an inspection device (not shown) equipped with the spectral interferometer 320 configured to detect the separation of the first wafer W1 and the second wafer W2 may be independently disposed in the wafer processing system 1.

Moreover, in the above-described example, whether the second wafer W2 is separated from the first wafer W1 is determined by detecting the space S formed at the interface between the first wafer W1 and the second wafer W2 (by detecting that the thickness t is greater than zero (t>0)). However, the method of inspecting the separation state is not limited thereto.

Specifically, in the combined wafer T in which the space S is formed at the interface between the first wafer W1 and the second wafer W2 in the laser radiating device 310, it is assumed that the height of the combined wafer T (more specifically, the height position of the rear surface W2b of the second wafer W2) changes due to the separation of the second wafer W2 and the laser absorption layer P, as illustrated in FIG. 22. In FIG. 22, the position of the second wafer W2 before the formation of the space S is indicated by a dashed line, and the position of the second wafer W2 after the formation of the space S is marked by a solid line.

Therefore, when determining whether or not the space S is formed in order to investigate the separation state of the first wafer W1 and the second wafer W2, the height of the combined wafer T may be measured.

As a specific example, an optical flat (reference horizontal plane) may be provided on the spectral interferometer 320, and interference (reflection spectrum) of reflection light from this optical flat and reflection light from the rear surface W2b of the second wafer W2 may be obtained. In this case, a difference in the height of the reference horizontal plane and the combined wafer T is calculated before and after the formation of the space S, and if this difference changes before and after the formation of the space S, there may be made a determination that the space S is formed.

Alternatively, in case that the region where the bonding strength is not supposed to be reduced is formed at a part of the interface between the second wafer W2 and the laser absorption layer P as shown in FIG. 19, if this region has the same height as the optical flat, there is made a determination that the space S is not formed.

Furthermore, when measuring the height of the combined wafer T (height position of the rear surface W2b of the second wafer W2) in this manner, instead of the thickness t of the space S, which is the measurement result used for the comparison with the first threshold value in the above-described exemplary embodiment, a variation amount t2 (see FIG. 22) in the height of the combined wafer T caused by the formation of the space S can be used as the measurement result used for the comparison with the first threshold value.

In addition, instead of or in addition to the spectral interferometer 320, a displacement meter (not shown) may be provided above the chuck 100 to measure a distance from this displacement meter to the rear surface W2b of the second wafer W2. In other words, whether or not the separation of the first wafer W1 and the second wafer W2 has occurred may be determined by detecting, for example, a variation amount in the distance to the rear surface W2b of the second wafer W2 before and after the formation of the space S, or a difference between the distance to the rear surface W2b in the region where the space S is formed and the distance to the rear surface W2b in the region where the bonding strength is not reduced (see FIG. 19). In this case, the device may be simply prepared by replacing the spectral interferometer 320 with the non-illustrated displacement meter (length measurement sensor) in the configuration of the laser radiating device 310 shown in FIG. 20.

Further, in the above-described laser radiating device, the laser light L is radiated sequentially to the preset central region R1 and peripheral region R2 (see FIG. 10) of the chuck 100. However, determination upon whether or not to radiate the laser light L to the central region R1 may be made prior to performing the radiation of the laser light L to the central region R1, for example.

Specifically, in the radiation of the laser light L to the combined wafer T (laser absorption layer P), position information of the peripheral region R2 is first acquired prior to performing radiation of the laser light L to the peripheral region R2. The acquired position information may be, as an example, a deviation amount (a distance between the acquirer and the combined wafer T) obtained by the displacement meter such as the length measurement sensor.

Once the position information of the peripheral region R2 is acquired, radiation of the laser light L to the peripheral region R2 is started. Here, the method of radiating the laser light L to the peripheral region R2 is the same as the above-described method of radiating the laser light L.

Subsequently, prior to performing radiation of the laser light L to the central region R1, position information of the peripheral region R2 is acquired again. This reacquisition of the position information may be performed by temporarily ceasing the laser processing (rotation of the combined wafer T and the radiation of the laser light L) before radiating the laser light L to the central region R1, or may be performed throughout the laser processing of the peripheral region R2.

Here, if there is no change in the position information of the peripheral region R2 before and after the radiation of the laser light L to the peripheral region R2, or if a change, if any, is not equal to or greater than a predetermined threshold value, it is considered that in the peripheral region R2, complete separation has not occurred at the interface between the second wafer W2 and the laser absorption layer P, and the bonding strength is still maintained. Meanwhile, if there is a change equal to or greater than the threshold value in the position information of the peripheral region R2 before and after the radiation of the laser light L, it is considered that separation has occurred at the interface between the second wafer W2 and the laser absorption layer P due to a certain factor during the radiation of the laser light L to the peripheral region R2, so the bonding strength has decreased.

When the bonding strength is deemed to be maintained as there is no change equal to or greater than the threshold value in the position information of the peripheral region R2 before and after the radiation of the laser light L, the radiation of the laser light L to the central region R1 is continued.

The combined wafer T with the reduced bonding strength between the second wafer W2 and the laser absorption layer P is then transferred to the separating device 32, where the first wafer W1 and the second wafer W2 are separated.

Meanwhile, when the bonding strength is deemed to be reduced as there is a change equal to or greater than the threshold value in the position information of the peripheral region R2 before and after the radiation of the laser light L, the laser light L is not radiated to the central region R1. Accordingly, the bonding strength between the second wafer W2 and the laser absorption layer P is maintained in the central region R1.

In this case, the combined wafer T is collected from the laser radiating device without being sent to the separating device 32. At this time, the combined wafer T may be collected into a cassette via a transfer device, or may be removed from the laser radiating device manually by the operator.

In this way, by determining whether or not to radiate the laser light L to the central region R1 depending on, for example, the separation state of the peripheral region R2, complete separation at the entire interface between the second wafer W2 including the central region R1 and the laser absorption layer P can be suppressed, so that the combined wafer T can be safely carried out without dropping the second wafer W2 in the laser radiating device.

In the present disclosure, the position information of the peripheral region R2 is obtained before performing the radiation of the laser light L to the peripheral region R2, and the separation state is determined by comparing the position information before the radiation of the laser light L with the position information after the radiation of the laser light L. If, however, the separation state in the peripheral region R2 can be determined without comparing the position information before and after the radiation of the laser light L, it is not necessary to obtain the position information before the radiation of the laser light L, and it may be sufficient to obtain the position information, etc., at least before the radiation of the laser light L to the central region R1 to check the separation state.

Additionally, in the above-described exemplary embodiment, the laser absorption layer P, the device layer D2, and the surface film F2 are stacked in this order on the front surface W2a of the second wafer W2, and the interface between the laser absorption layer P and the second wafer W2 is set as the separation surface between the first wafer W1 and the second wafer W2. However, the position of the separation surface is not limited thereto.

As a specific example, on the front surface W2a side of the second wafer W2, a separation accelerating film (not shown) for accelerating the separation between the first wafer W1 and the second wafer W2 may be formed between the second wafer W2 and the laser absorption layer P, and an interface between this separation accelerating film and the second wafer W2 may be set as the separation surface. In this case, it is desirable that the separation accelerating film is made of a material that allows the adhesion between the separation accelerating film and the second wafer W2 (silicon, etc.) to be at least smaller than the adhesion between the separation accelerating film and the laser absorption layer P (oxide film).

Here, it should be noted that the above-described exemplary embodiments are illustrative in all aspects and are not anyway limiting. The above-described exemplary embodiments may be omitted, replaced and modified in various ways without departing from the scope and the spirit of claims.

### Explanation of Codes

1: Wafter processing system
31: Laser radiating device
40: Control device
100: Chuck
104: Rotating mechanism
105: Driving mechanism
108: Contact sensor
110: Laser radiator
120: Imaging mechanism
L: Laser light
T: Combined wafer
W1: First wafer
W2: Second wafer

1. A substrate processing system of processing a substrate, comprising:
a substrate holder having a holding surface on which the substrate is to be held;
a driving mechanism configured to move the substrate holder in a horizontal direction;
a rotating mechanism configured to rotate the substrate holder;
a laser radiator configured to radiate laser light to the substrate held on the holding surface to form a separation surface serving as a starting point for separation of the substrate; and
a detecting mechanism configured to detect the separation starting from the separation surface in the substrate held by the substrate holder.

2. The substrate processing system of claim 1,
wherein the detecting mechanism comprises:
an acquirer configured to acquire position information of at least an upper substrate above the separation surface in the substrate; and
a determiner configured to determine whether or not the upper substrate is separated, based on the position information acquired by the acquirer.

3. The substrate processing system of claim 2,
wherein the detecting mechanism is configured to:
acquire the position information of the upper substrate before and after radiation of the laser light to detect a deviation amount of a center of the upper substrate with respect to a center of the substrate holder in the horizontal direction before and after the radiation of the laser light, and then
determine whether or not the upper substrate is separated based on a difference between the deviation amount before the radiation of the laser light and the deviation amount after the radiation of the laser light.

4. The substrate processing system of claim 2,
wherein the detecting mechanism is configured to:
acquire the position information of the upper substrate and position information of a lower substrate below the separation surface in the substrate before and after radiation of the laser light to detect a deviation amount of the upper substrate with respect to the lower substrate in the horizontal direction before and after the radiation of the laser light, and then
determine whether or not the upper substrate is separated based on a difference between the deviation amount before the radiation of the laser light and the deviation amount after the radiation of the laser light.

5. The substrate processing system claim 2,
wherein the detecting mechanism is configured to:
acquire the position information of the upper substrate and position information of a lower substrate below the separation surface in the substrate after radiation of the laser light to detect a deviation amount of the upper substrate with respect to the lower substrate in the horizontal direction, and then
determine whether or not the upper substrate is separated, based on the deviation amount.

6. The substrate processing system of claim 2,
wherein the detecting mechanism is configured to:
acquire position information of the upper substrate in a height direction, and then
determine whether or not the upper substrate is separated, based on a variation amount in a height position of the upper substrate before and after radiation of the laser light, or based on a difference between a previously acquired reference horizontal plane and the acquired position information of the upper substrate in the height direction.

7. The substrate processing system of claim 1,
wherein the detecting mechanism comprises:
multiple contact sensors configured to surround the substrate on the holding surface; and
a determiner configured to determine whether or not the substrate is separated, based on information obtained by the contact sensors, and
the determiner is configured to determine whether or not an upper substrate above the separation surface in the substrate is separated by detecting a contact between the contact sensors and the upper substrate.

8. The substrate processing system claim 1,
wherein the detecting mechanism comprises:
a spectral interferometer configured to detect a first height position and a second height position, the first height position being different from the second height position in a thickness direction of the substrate, and
the spectral interferometer comprises:
a head configured to radiate measurement light toward the substrate and detect interference between reflection light from the first height position and reflection light from the second height position; and
an analyzer configured to measure a distance between the first height position and the second height position based on the interference of the reflection light.

9. The substrate processing system of claim 1,
wherein the substrate holder comprises:
multiple elevating pins configured to support the substrate held on the holding surface from below, and move the substrate up and down; and
multiple substrate drop prevention pins configured to surround the substrate held on the holding surface, and configured to be moved up and down as one body with the elevating pins.

10. The substrate processing system claim 1, further comprising:
a separating device configured to separate the substrate starting from the separation surface; and
a substrate transfer mechanism configured to transfer the substrate,
wherein the substrate transfer mechanism comprises multiple transfer arms,
at least one of the multiple transfer arms has multiple guide pins arranged to surround the substrate, and
the substrate transfer mechanism is configured to transfer the substrate after being irradiated with the laser light by holding the substrate with the transfer arm having the multiple guide pins when the substrate is transferred from the laser radiator to the separating device.

11. The substrate processing system of claim 1,
wherein the driving mechanism is configured to move the substrate holder between a delivery position where the substrate is handed over to the substrate holder and a processing position where the separation surface is formed by radiation of the laser light,
the substrate processing system further includes a control mechanism configured to control at least an operation of the driving mechanism, the at least one operation includes controlling an acceleration in moving the substrate holder from the processing position to the delivery position after the radiation of the laser light to be higher than an acceleration in moving the substrate holder from the delivery position to the processing position before the radiation of the laser light.

12. The substrate processing system of claim 1, further comprising:
a separating device configured to separate the substrate starting from the separation surface;
a substrate transfer mechanism configured to transfer the substrate; and
a control mechanism,
wherein when separation of the substrate starting from the separation surface is detected by the detecting mechanism, the control mechanism is configured to control the substrate transfer mechanism to transfer the substrate to the separating device, and set a transfer speed of the substrate in transferring the substrate to the separating device to be lower than a specified speed.

13. The substrate processing system of claim 1, further comprising:
a substrate transfer mechanism configured to transfer the substrate;
a transfer pad configured to attract and hold the substrate held by the substrate holder from above; and
a control mechanism,
wherein when separation of the substrate starting from the separation surface is detected by the detecting mechanism, the control mechanism is configured to:
control the transfer pad to attract and hold an upper substrate above the separation surface in the substrate, and to separate the upper substrate from a lower substrate below the separation surface in the substrate;
control the substrate transfer mechanism to transfer the lower substrate held by the substrate holder; and
control the transfer pad to deliver the upper substrate attracted to and held by the transfer pad to the substrate transfer mechanism, and then transfer the upper substrate.

14. The substrate processing system of claim 1, further comprising:
a separating device configured to separate the substrate starting from the separation surface;
a substrate transfer mechanism configured to transfer the substrate; and
a control mechanism,
wherein when separation of the substrate starting from the separation surface is not detected by the detecting mechanism, the control mechanism is configured to control the substrate transfer mechanism to transfer the substrate, after being subjected to formation of the separation surface, to the separating device.

15. A substrate processing method of processing a substrate, comprising:
placing the substrate onto a holding surface of a substrate holder;
radiating laser light to the substrate held on the holding surface to form a separation surface serving as a starting point for separation of the substrate; and
detecting the separation starting from the separation surface in the substrate held by the substrate holder.

16. The substrate processing method of claim 15,
wherein the detecting of the separation of the substrate comprises:
acquiring position information of at least an upper substrate above the separation surface in the substrate; and
determining whether or not the upper substrate is separated, based on the acquired position information.

17. The substrate processing method of claim 16,
wherein in the detecting of the separation of the substrate, the position information of the upper substrate before and after radiation of the laser light is acquired to detect a deviation amount of a center of the upper substrate with respect to a center of the substrate holder in a horizontal direction before and after the radiation of the laser light, and
whether or not the upper substrate is separated is determined, based on a difference between the deviation amount before the radiation of the laser light and the deviation amount after the radiation of the laser light.

18. The substrate processing method of claim 16,
wherein in the detecting of the separation of the substrate, the position information of the upper substrate and position information of a lower substrate below the separation surface in the substrate before and after radiation of the laser light are acquired to detect a deviation amount of the upper substrate with respect to the lower substrate in the horizontal direction before and after the radiation of the laser light, and
whether or not the upper substrate is separated is determined, based on a difference between the deviation amount before the radiation of the laser light and the deviation amount after the radiation of the laser light.

19. The substrate processing method of claim 16,
wherein in the detecting of the separation of the substrate, the position information of the upper substrate and position information of a lower substrate below the separation surface in the substrate after radiation of the laser light are acquired to detect a deviation amount of the upper substrate with respect to the lower substrate in the horizontal direction, and
whether or not the upper substrate is separated is determined, based on the deviation amount.

20. The substrate processing method of claim 16,
wherein in the detecting of the separation of the substrate, position information of the upper substrate in a height direction is acquired, and
whether or not the upper substrate is separated is determined, based on a variation amount in a height position of the upper substrate before and after radiation of the laser light, or based on a difference between a previously acquired reference horizontal plane and the acquired position information of the upper substrate in the height direction.

21. The substrate processing method of claim 15,
wherein the detecting of the separation of the substrate is determined by detecting a contact between an upper substrate above the separation surface in the substrate and multiple contact sensors configured to surround the substrate on the holding surface.

22. The substrate processing method of claim 15,
wherein the detecting of the separation of the substrate is determined by detecting a first height position and a second height position, which are different in a thickness direction of the substrate.

23. The substrate processing method of claim 15,
wherein the radiating laser light to the substrate is performed by a laser radiating device in a processing position,
the method further comprises moving the substrate holder between a delivery position where the substrate is handed over to the substrate holder and the processing position where the separation surface is formed by radiation of the laser light, and
an acceleration in moving the substrate holder from the processing position to the delivery position after the radiation of the laser light is set higher than an acceleration in moving the substrate holder from the delivery position to the processing position before the radiation of the laser light.
